(19) United States
(12) Patent Application Publication
(10) Pub. No.: US 2026/0371770 A1
(43) Pub. Date: Nov. 19, 2026

(54) PHOTOELECTRIC CONVERSION DEVICE, PHOTOELECTRIC CONVERSION SYSTEM, MOVING BODY, AND EQUIPMENT

(71) Applicant: CANON KABUSHIKI KAISHA, Tokyo (JP)

(72) Inventors: DAIKI SHIRAHIGE, Kanagawa (JP); SHINYA ICHINO, Saitama (JP)

(21) Appl. No.: 19/663,742

(22) Filed: Apr. 30, 2026

(30) Foreign Application Priority Data
May 16, 2025 (JP) 2025-082853

(51) Int. Cl. H10F 39/00; H04N 25/59

(52) U.S. Cl. CPC H10F 39/813; H10F 39/8053; H10F 39/8063; H04N 25/59

(57) ABSTRACT

A photoelectric conversion device that includes a plurality of pixel groups including first and second pixel groups arranged to share a microlens, each pixel group being constituted by one or multiple pixels, and color filters covering the plurality of pixel groups and corresponding to a plurality of colors, is provided. Photoelectric conversion elements arranged in pixels constituting each pixel group share one floating diffusion, the first pixel group is constituted by multiple pixels, the one floating diffusion receives signals which are output from the photoelectric conversion elements arranged in pixels constituting a corresponding pixel group and correspond to color filters of the same color, a pixel constituting the first pixel group and a pixel constituting the second pixel group are different from each other in the number of charges generated in a case where light with a first intensity enters the microlens.

### BACKGROUND

### Field of the Technology

The present disclosure relates to a photoelectric conversion device, a photoelectric conversion system, a moving body, and equipment.

### Description of the Related Art

US 2017/0347042 describes an imaging system that expands the dynamic range based on signals captured by pixels with different sensitivities.

There is a demand for not only expanding the dynamic range but also improving the SN ratio in a photoelectric conversion device.

### SUMMARY

Some embodiments of the present disclosure provide a technique advantageous in improving the characteristics of a photoelectric conversion device.

According to some embodiments, a photoelectric conversion device that comprises a plurality of pixel groups including a first pixel group and a second pixel group arranged to share a microlens, each pixel group being constituted by one or multiple pixels, and color filters covering the plurality of pixel groups and corresponding to a plurality of colors, wherein photoelectric conversion elements arranged in pixels constituting each pixel group share one floating diffusion, the first pixel group is constituted by multiple pixels, the one floating diffusion receives signals which are output from the photoelectric conversion elements arranged in pixels constituting a corresponding pixel group and correspond to color filters of the same color, a pixel constituting the first pixel group and a pixel constituting the second pixel group are different from each other in the number of charges generated in a case where light with a first intensity enters the microlens, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing an arrangement example of a photoelectric conversion device according to an embodiment;

FIG. 2 is an equivalent circuit diagram showing an arrangement example of the pixels of the photoelectric conversion device shown in FIG. 1;

FIG. 3 is an equivalent circuit diagram showing an arrangement example of the pixels of the photoelectric conversion device shown in FIG. 1;

FIGS. 4A to 4D are plan views each showing an arrangement example of the pixels of the photoelectric conversion device shown in FIG. 1;

FIGS. 5A to 5C are plan views each showing an arrangement example of the pixels of the photoelectric conversion device shown in FIG. 1;

FIGS. 6A and 6B are a plan view and a sectional view showing an arrangement example of the pixels of the photoelectric conversion device shown in FIG. 1;

FIG. 7 is an equivalent circuit diagram showing an arrangement example of the pixels of the photoelectric conversion device shown in FIG. 1;

FIG. 8 is a view showing an example of the output characteristics of the pixels of the photoelectric conversion device shown in FIG. 1:

FIG. 9 is a flowchart showing an example of the HDR processing of the photoelectric conversion device shown in FIG. 1;

FIG. 10 is a plan view showing an arrangement example of the pixels of the photoelectric conversion device shown in FIG. 1;

FIG. 11 is a plan view showing an arrangement example of the pixels of the photoelectric conversion device shown in FIG. 1;

FIG. 12 is a plan view showing an arrangement example of the pixels of the photoelectric conversion device shown in FIG. 1;

FIG. 13 is a plan view showing an arrangement example of the pixels of the photoelectric conversion device shown in FIG. 1;

FIGS. 14A and 14B are a plan view and a sectional view showing an arrangement example of the pixels of the photoelectric conversion device shown in FIG. 1;

FIGS. 15A and 15B are a plan view and a sectional view showing an arrangement example of the pixels of the photoelectric conversion device shown in FIG. 1;

FIG. 16 is an equivalent circuit diagram showing an arrangement example of the pixels of the photoelectric conversion device shown in FIG. 1;

FIG. 17 is a plan view showing an arrangement example of the pixels of the photoelectric conversion device shown in FIG. 1;

FIG. 18 is a functional block diagram of a photoelectric conversion system using the photoelectric conversion device according to the embodiment;

FIGS. 19A and 19B are functional block diagrams of a photoelectric conversion system using the photoelectric conversion device according to the embodiment;

FIG. 20 is a functional block diagram of a photoelectric conversion system using the photoelectric conversion device according to the embodiment;

FIG. 21 is a functional block diagram of a photoelectric conversion system using the photoelectric conversion device according to the embodiment; and

FIGS. 22A and 22B are views each showing a photoelectric conversion system using the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

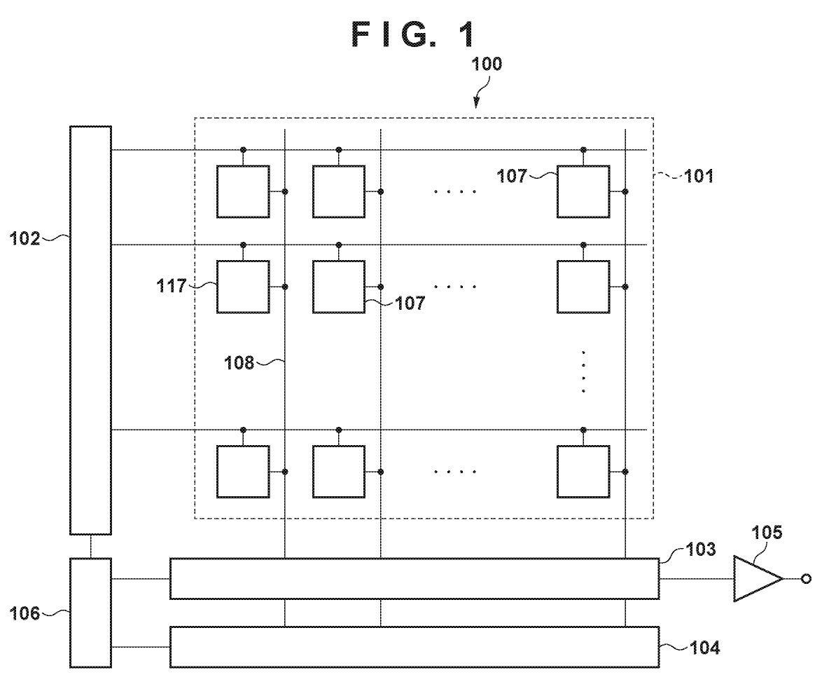

With reference to FIGS. 1-17, a photoelectric conversion device according to an embodiment of the present disclosure will be described. FIG. 1 is a block diagram showing an arrangement example of a photoelectric conversion device 100 according to this embodiment. The photoelectric conversion device 100 can include a pixel array 101, a vertical scanning circuit 102, a column amplification circuit 103, a horizontal scanning circuit 104, an output circuit 105, and a control circuit 106. The photoelectric conversion device 100 may be a semiconductor device formed on a semiconductor substrate such as a silicon substrate, and is a CMOS image sensor in this embodiment. The pixel array 101 includes a plurality of pixels 107 and 117 which are two-dimensionally arranged to form a plurality of rows and a plurality of columns. The vertical scanning circuit 102 supplies, to the pixel 107, a plurality of control signals for controlling a plurality of transistors arranged in the pixel 107 to an ON (conductive) state or an OFF (non-conductive) state. Column signal lines 108 are provided so as to correspond to the respective columns of the pixels 107 and 117, and signals output from the pixels 107 and 117 are read out to the column signal lines 108 for each column. The column amplification circuit 103 can amplify pixel signals output to the column signal lines 108, and perform processing such as correlation double sampling processing based on signals at the time of reset and signals at the time of photoelectric conversion of the pixels 107 and 117. The horizontal scanning circuit 104 includes a switch connected to an amplifier of the column amplification circuit 103, and supplies a control signal for controlling the switch to a conductive or non-conductive state. The control circuit 106 controls the vertical scanning circuit 102, the column amplification circuit 103, and the horizontal scanning circuit 104. The output circuit 105 includes a buffer amplifier, a differential amplifier, or the like, and outputs the pixel signal from the column amplification circuit 103 to a signal processing unit or the like outside the photoelectric conversion device 100. The photoelectric conversion device 100 may further include, for example, an analog/digital (A/D) conversion unit. In that case, the photoelectric conversion device 100 outputs a digital pixel signal to the outside of the photoelectric conversion device 100.

Each of the pixels 107 and 117 includes a photoelectric conversion element such as a photodiode. The pixel 107 is an effective pixel where light enters the photoelectric conversion element and a pixel signal corresponding to the amount of light entering the photoelectric conversion element is output. The pixel 117 is an optical black pixel (OB pixel) where the photoelectric conversion element is shielded from light, and the output signal therefrom is used as a black level reference. The pixels 117 are arranged in some rows and/or some columns of the plurality of rows and the plurality of columns forming the pixel array 101, and are generally arranged in the row and column contacting two sides around the pixel array 101. The column where only the pixels 117 are arranged may be referred to as a horizontal OB pixel region, and the pixels arranged in the horizontal OB pixel region may be referred to as horizontal OB pixels. The row where only the pixels 117 are arranged may be referred to as a vertical OB pixel region, and the pixels arranged in the vertical OB pixel region may be referred to as vertical OB pixels. For the sake of illustrative simplicity, FIG. 1 shows an example where the pixels 117 are arranged in the leftmost column (first column) of the plurality of columns of the pixel array 101, and the pixels 107 are arranged in the other columns (from the second column to the Nth column). However, the horizontal OB pixel region is typically formed by multiple columns.

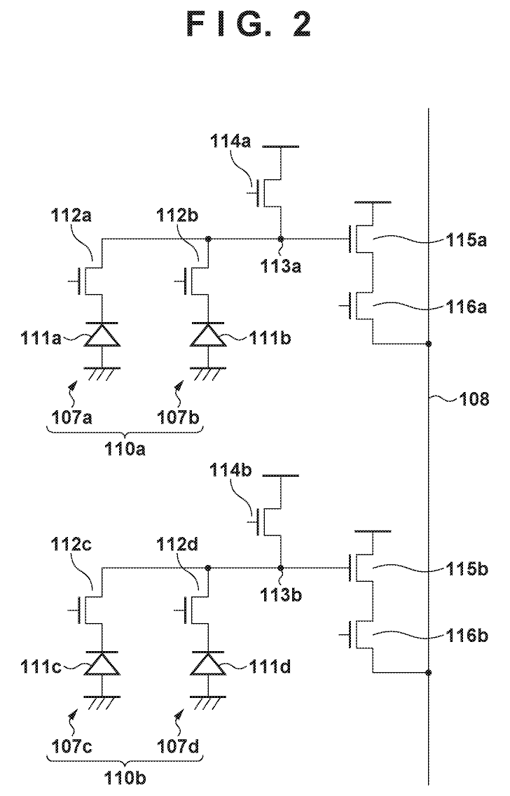

FIG. 2 is an equivalent circuit diagram including the pixels 107. In this embodiment, the photoelectric conversion device 100 includes a plurality of pixel groups 110 each constituted by one or multiple pixels 107. FIG. 2 shows a pixel group 110a and a pixel group 110b arranged adjacent to each other. Hereinafter, when indicating a specific pixel group among the pixel groups 110, a suffix such as "a" of the pixel group 110a will be added following the reference numeral, and when indicating any of the pixel groups 110, it will be simply indicated as the pixel group "110". This applies to other components in a similar manner.

The pixel 107 includes a photoelectric conversion element 111 and a transfer transistor 112. The photoelectric conversion elements 111 arranged in the pixels 107 constituting each pixel group 110 share one floating diffusion (FD) 113. It can also be said that one shared FD 113 defines each pixel group 110. In addition, the photoelectric conversion elements 111 arranged in the pixels 107 constituting each pixel group 110 share a reset transistor 114, an amplification transistor 115, and a selection transistor 116, which are arranged closer to the column signal line 108 than the FD 113. The control signals for controlling the transfer transistor 112, the reset transistor 114, the amplification transistor 115, and the selection transistor 116 are supplied from the vertical scanning circuit 102 as described above. FIG. 2 shows the configuration of the pixel 107, and the pixel 117 has a similar configuration except for the photoelectric conversion element 111 shielded from light. One or multiple pixels 117 constitute one pixel group 110.

For example, a photodiode is used for the photoelectric conversion element 111. The photoelectric conversion element 111 photoelectrically converts incident light, and accumulates signal charges generated by photoelectric conversion. The transfer transistor 112 is controlled by the control signal supplied to the gate and, when it is set in the ON state, transfers the charges accumulated in the photoelectric conversion element 111 to the FD 113. The drain of the amplification transistor 115 is connected to a power supply voltage line VDD, and the source thereof is connected to the drain of the selection transistor 116. The source of the selection transistor 116 is connected to the column signal line 108. The column signal line 108 is connected to a constant current source (not shown). The selection transistor 116 is controlled by the control signal supplied to the gate and, when it is set in the ON state, connects the source of the amplification transistor 115 to the column signal line 108, thereby causing it to function as a source follower. At this time, an output signal Vout based on the voltage of the FD 113 is output to the column amplification circuit 103 shown in FIG. 1 via the column signal line 108 of each column.

In this embodiment, at least some pixels 107 in the pixel array 101 constitute the pixel group 110 for sharing the FD 113. A pixel group 110a includes a pixel 107a and a pixel 107b, and photoelectric conversion elements 111a and 111b arranged in the pixels 107a and 107b share an FD 113a. A pixel group 110b includes a pixel 107c and a pixel 107d, and photoelectric conversion elements 111c and 111d arranged in the pixels 107c and 107d share an FD 113b. Here, the pixels 107a and 107b constituting the pixel group 110a and the pixels 107c and 107d constituting the pixel group 110b are different from each other in the number of charges generated when light with the same intensity enters. For example, each of the pixel 107a and the pixel 107b generates the first amount of charges when light with a given intensity enters, and each of the pixel 107c and the pixel 107d generates the second amount of charges different from the first amount when light with the same intensity enters. For example, in the pixels 107c and 107d, a light shielding film, which shields at least part of light, is arranged between the photoelectric conversion elements 111c and 111d and the light incident surface of the semiconductor substrate where the pixels 107c and 107d are arranged. On the other hand, in the pixels 107a and 107b, such a light shielding film is not arranged or a light shielding film is arranged which is smaller than the light shielding film arranged in the pixels 107c and 107d. Accordingly, the sensitivity to incident light may be different between the pixels 107a and 107b and the pixels 107c and 107d. As a result, when light with the same intensity enters, the charge generation amount is different between the pixels 107a and 107b and the pixels 107c and 107d. It can also be said that the pixels 107a and 107b and the pixels 107c and 107d are different from each other in the voltage of the signal output when light with the same intensity enters.

In this manner, the pixels 107 that generate the same amount of charges (have the same sensitivity) with respect to incident light share one FD 113 and constitute the pixel group 110. Since the FD 113 is shared by the pixels 107 for each pixel group 110, miniaturization of the pixel 107 can be achieved. This is because the number of transistors per pixel 107 effectively decreases. In a case where two pixels 107 are arranged in one pixel group 110 as shown in FIG. 2, three transistors including the reset transistor 114, the amplification transistor 115, and the selection transistor 116 can be reduced as compared to a case where these transistors are arranged for each pixel. In addition, since the signal charges are summed and read out, sharing the FD 113 has the effect of shortening the readout time and improving the SN ratio.

Furthermore, as shown in FIG. 2, the pixels 107 having different sensitivities are arranged in the pixel array 101. By using signals of the high-sensitivity pixels 107 under a low illuminance environment and using signals of the low-sensitivity pixels 107 under a high illuminance environment, high dynamic range (HDR) image capturing capable of capturing a wider illuminance range is achieved. Here, the high sensitivity and the low sensitivity can be defined by the number of charges generated when light with the same intensity enters, as described above. In this embodiment, in the pixel groups 110 where the pixels 107 having different sensitivities are arranged, the pixels 107 having the same sensitivity share the FD 113. This enables image capturing with the improved SN ratio. For example, assume that the pixels 107a and 107b have the higher sensitivity than the pixels 107c and 107d shown in FIG. 2. The photoelectric conversion elements 111a and 111b arranged in the high-sensitivity pixels 107a and 107b share the same FD 113a, and a binning operation of summing the signals of the pixels 107a and 107b is performed. This enables image capturing under low illuminance and higher SN ratio.

It has been described above that the sensitivity to light with the same intensity is different between the pixels 107a and 107b and the pixels 107c and 107d. However, the method for changing the number of charges generated with respect to light with the same intensity is not limited to this. For example, the accumulation time in the pixels 107a and 107b arranged in the pixel group 110a and the accumulation time in the pixels 107c and 107d arranged in the pixel group 110b during image capturing in the photoelectric conversion device 100 may be different from each other. An effect similar to the effect described above can also be obtained by setting different charge generation and accumulation times in the photoelectric conversion elements 111 arranged in the pixels 107. For example, the accumulation time in each of the photoelectric conversion elements 111a and 111b arranged in the pixels 107a and 107b of the pixel group 110a sharing the FD 113a may be set longer than the accumulation time in each of the photoelectric conversion elements 111c and 111d arranged in the pixels 107c and 107d of the pixel group 110b sharing the FD 113b. In this case, by using the signals obtained by the pixel group 110a, the SN ratio in low-illuminance image capturing can be improved while obtaining the effect of improving the sensitivity by binning. This can improve the image capturing performance with low illuminance as compared to a case where the accumulation time is simply increased without performing the binning operation.

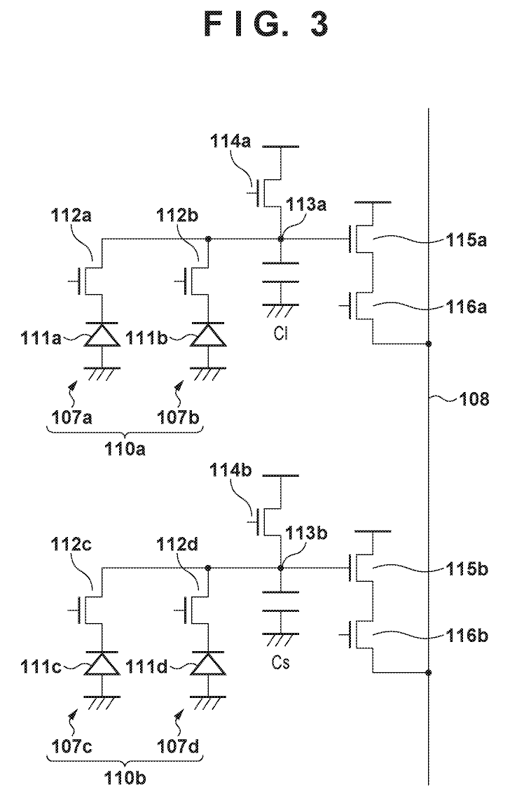

For example, as shown in FIG. 3, considering the case of performing the binning operation, the magnitude of a capacitance Cl of the FD 113a arranged corresponding to the pixel group 110a and the magnitude of a capacitance Cs of the FD 113b arranged corresponding to the pixel group 110b may be different from each other. For example, assume a case where the pixels 107a and 107b constituting the pixel group 110a have a higher sensitivity or perform a longer accumulation operation than the pixels 107c and 107d constituting the pixel group 110b. In this case, the capacitance Cl of the FD 113a arranged corresponding to the pixel group 110a is set smaller than the capacitance Cs of the FD 113b arranged corresponding to the pixel group 110b. This can increase the charge-voltage conversion gain, and improve the SN ratio with lower illuminance. On the other hand, the capacitance Cs of the FD 113b arranged corresponding to the pixel group 110b, which has a low sensitivity or performs a short accumulation operation, is set larger than the capacitance Cl of the FD 113a. This enables image capturing of a high-illuminance object without highlight blowout.

When binning is performed between the pixels 107 having different sensitivities or accumulation times, signal charges accumulated under different image capturing conditions are mixed so a proper signal according to the sensitivity or accumulation time of each pixel 107 is not output. On the other hand, in this embodiment, binning is performed between the pixels 107 having the same sensitivity or accumulation time. Therefore, a proper signal according to the pixel characteristics or image capturing condition is output. As described above, this can achieve not only the expansion of the dynamic range but also the improvement of the SN ratio. The method for changing the number of charges generated with respect to light with the same sensitivity between the pixels 107 arranged in the respective pixel groups 110 may use the sensitivity and accumulation time of the pixel 107 and the capacitance of the FD 113 described above individually or in combination, as appropriate.

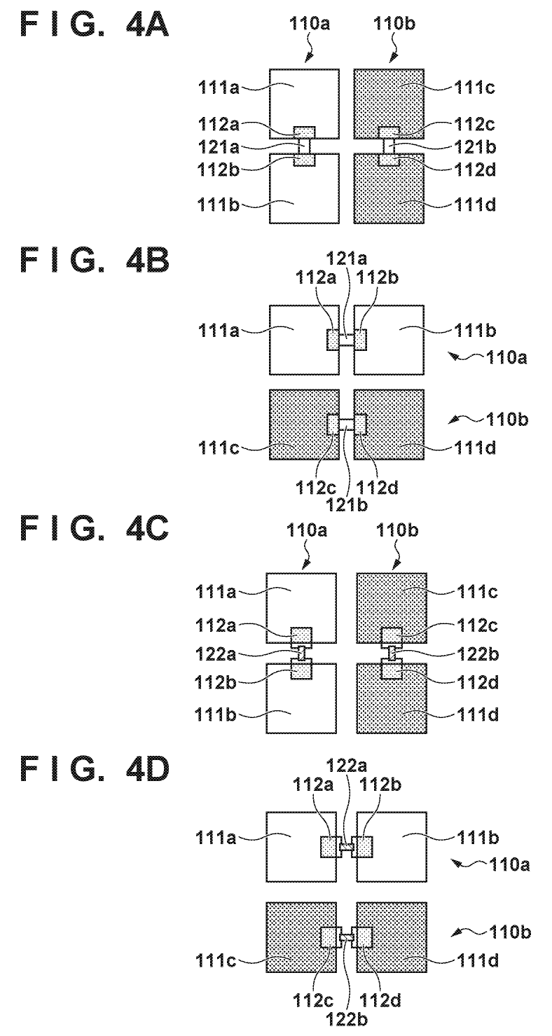

Each of FIGS. 4A and 4B shows a example of the planar layout of the pixel groups 110a and 110b focusing on the FDs 113a and 113b shown in FIG. 2. Each of FIGS. 4A and 4B shows, as an example of the FD 113, a diffusion layer sharing FD 121 that shares a diffusion layer provided in the semiconductor substrate. The photoelectric conversion elements 111a and 111b of the pixels 107a and 107b constituting the pixel group 110a are connected to a diffusion layer sharing FD 121a serving as the FD 113a via the transfer transistors 112a and 112b. Similarly, the photoelectric conversion elements 111c and 111d of the pixels 107c and 107d constituting the pixel group 110b are connected to a diffusion layer sharing FD 121b serving as the FD 113b via the transfer transistors 112c and 112d. For example, as shown in FIG. 4A, two photoelectric conversion elements 111 arranged above and below in the extending direction of the column signal line 108 (the column signal line 108 is not shown in FIGS. 4A to 4D) may share one diffusion layer sharing FD 121 (FD 113). Alternatively, for example, as shown in FIG. 4B, two photoelectric conversion elements 111 arranged left and right in a direction crossing the extending direction of the column signal line 108 may share one diffusion layer sharing FD 121 (FD 113).

Each of FIGS. 4C and 4D shows, as an example of the FD 113, a wiring sharing FD 122 that shares a wiring pattern made of a conductor such as a metal or polysilicon provided on the semiconductor substrate. The photoelectric conversion elements 111a and 111b of the pixels 107a and 107b constituting the pixel group 110a are connected to a wiring sharing FD 122a serving as the FD 113a via the transfer transistors 112a and 112b. Similarly, the photoelectric conversion elements 111c and 111d of the pixels 107c and 107d constituting the pixel group 110b are connected to a wiring sharing FD 122b serving as the FD 113b via the transfer transistors 112c and 112d. For example, as shown in FIG. 4C, two photoelectric conversion elements 111 arranged above and below in the extending direction of the column signal line 108 may share one wiring sharing FD 122 (FD 113). Alternatively, for example, as shown in FIG. 4D, two photoelectric conversion elements 111 arranged left and right in a direction crossing the extending direction of the column signal line 108 may share one wiring sharing FD 122 (FD 113). The wiring sharing FD 122 has a larger FD capacitance and a smaller charge voltage conversion gain than the diffusion layer sharing FD 121 since the wiring capacitance is added. On the other hand, the wiring sharing FD 122 has a higher design flexibility regarding FD sharing than the diffusion layer sharing FD 121. For example, the wiring sharing FD 122 allows the pixels 107 (photoelectric conversion elements 111) not adjacent to each other to share the FD.

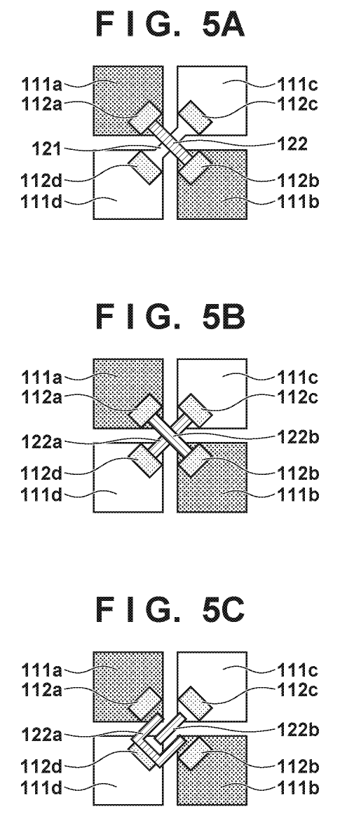

Each of FIGS. 5A-5C shows a layout example for diagonally sharing the FD. When combining signals with different image capturing conditions, if the optical barycentric position of the pixel 107 (photoelectric conversion element 111) is different between the image capturing signals to be combined, artifact may occur. For example, when the pixels 107 (photoelectric conversion elements 111) in two rows and two columns are considered as one unit for processing one pixel signal, by diagonally sharing the FD, it is possible to align the optical barycentric positions of image capturing signals, thereby suppress artifact.

FIG. 5A shows a layout example for diagonally sharing the FDs using the diffusion layer sharing FD 121 and the wiring sharing FD 122. The photoelectric conversion elements 111a and 111b of the pixels 107a and 107b constituting the pixel group 110a are connected to the wiring sharing FD 122 serving as the FD 113a via the transfer transistors 112a and 112b. On the other hand, the photoelectric conversion elements 111c and 111d of the pixels 107c and 107d constituting the pixel group 110b are connected to the diffusion layer sharing FD 121 serving as the FD 113b via the transfer transistors 112c and 112d. When the pixels 107 (photoelectric conversion elements 111) in two rows and two columns diagonally share the FDs, the layout efficiency can be improved by using not only the diffusion layer sharing FD 121 but also the wiring sharing FD 122.

Each of FIGS. 5B and 5C shows a layout example for diagonally sharing the FDs using the wiring sharing FDs 122a and 122b. As shown in FIG. 5B, the wiring sharing FD 122a uses a wiring pattern in, for example, the first layer, and the wiring sharing FD 122b uses a wiring pattern in the upper layer than the wiring sharing FD 122a, for example, in the second layer. This allows the pixels 107 (photoelectric conversion elements 111) in two rows and two columns to diagonally share the FDs. Alternatively, for example, as shown in FIG. 5C, the wiring sharing FDs 122a and 122b may be formed using wiring patterns in a signal layer. The diffusion layer sharing FD 121 and the wiring sharing FD 122 may be designed, as appropriate, in accordance with the magnitude of the capacitance required for the FD 113 arranged corresponding to each pixel group 110.

It has been described above that, in order to change, between the pixels 107 arranged in different pixel groups 110, the number of charges generated when light with the same intensity enters, the sensitivity is changed using the light shielding film or the like, or the accumulation time is changed. However, the method for changing the number of charges to be generated is not limited to this. A method for changing the number of charges to be generated between the pixels 107 arranged in different pixel groups 110 by allowing multiple pixels 107 (photoelectric conversion elements 111) to share one microlens 131 will be described below.

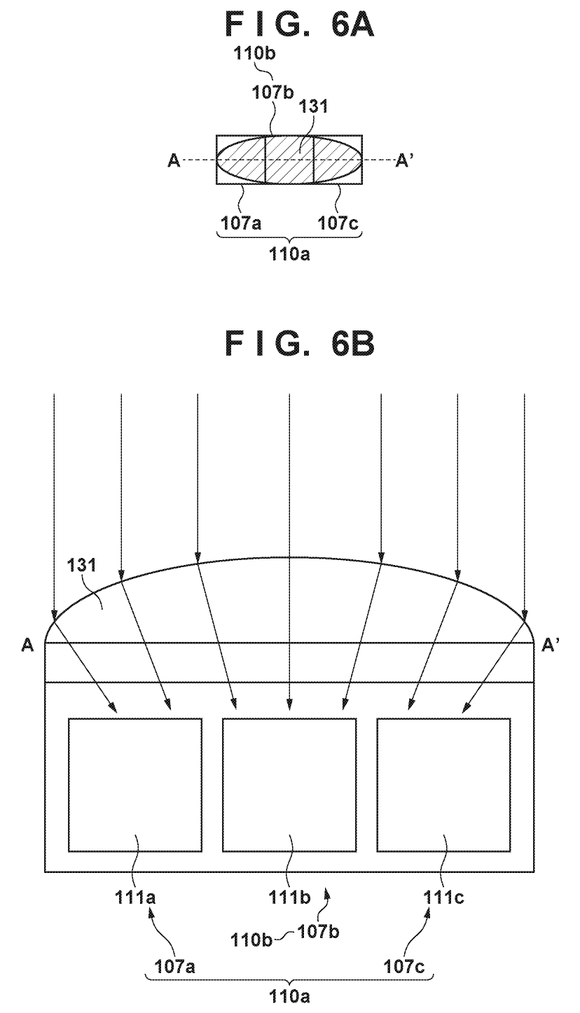

FIGS. 6A and 6B show an example where the pixels 107 have different sensitivities for the respective pixel groups 110 due to an optical structure using a microlens 131. The sensitivity of the pixel 107 depends on the amount of light entering the photoelectric conversion element 111 arranged in the pixel 107. Therefore, as shown in FIGS. 6A and 6B, depending on the arrangement position of the pixel 107 relative to the microlens 131 in a planar view, the sensitivity of the pixel 107 when light with a given intensity enters the microlens 131 can be changed among the pixels 107. For example, as shown in FIGS. 6A and 6B, consider a case where the microlens 131 is shared by three pixels 107a to 107c arrayed along one direction. The pixel 107b is arranged between the pixel 107a and 107c. In this case the sensitivity changes between the pixel 107b arranged in the center and the pixels 107a and 107c arranged at both ends. For example, the pixel 107b is arranged to overlap the center of the microlens 131. On the other hand, the pixels 107a and 107c are arranged at point-symmetric positions relative to the center of the microlens 131. Accordingly, when light with a given intensity enters the microlens 131, the amount of charges generated by the photoelectric conversion element 111b of the pixel 107b is larger than the amounts of charges generated by the photoelectric conversion elements 111a and 111c of the pixels 107a and 107c. That is, the sensitivity of the pixel 107b is higher than the sensitivities of the pixels 107a and 107c. The pixels 107a and 107c have the same sensitivity. In this manner, among the pixels 107a to 107c different in sensitivity due to the optical structure, the pixel 107a and the pixel 107c having the same sensitivity share the FD 113. That is, the pixel 107a and the pixel 107c constitute one pixel group 110a, and the pixel 107b constitutes one pixel group 110b. This enables a binning readout operation as described above, and implements the photoelectric conversion device 100 with the improved SN ratio.

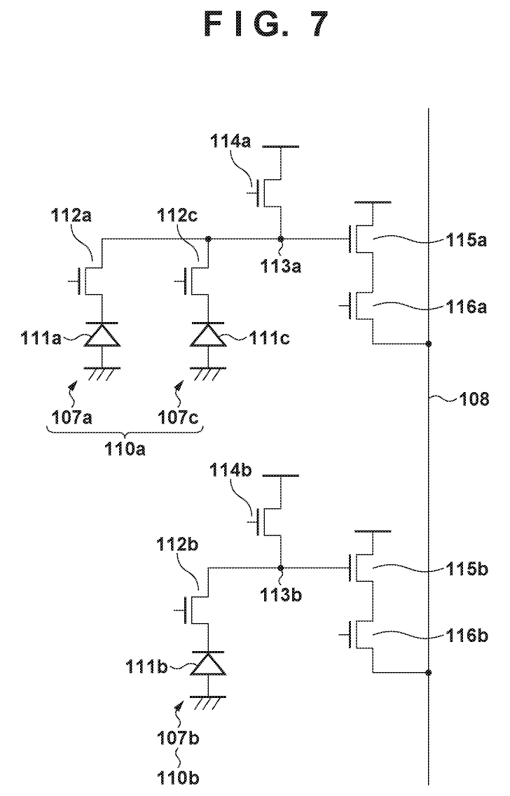

FIG. 7 is an equivalent circuit diagram including the pixels 107 with the arrangement shown in FIGS. 6A and 6B. As shown in FIG. 7, the pixel 107a (photoelectric conversion element 111a) and the pixel 107c (photoelectric conversion element 111c) having the same sensitivity constitute the pixel group 110a, and the photoelectric conversion elements 111a and 111c share one FD 113a. The pixel 107b (photoelectric conversion element 111b) having the sensitivity different from that of the pixels 107a and 107c (photoelectric conversion elements 111a and 111c) constitutes the pixel group 110b, and is connected to the FD 113b different from the FD 113a. With this, a binning operation can be performed between the pixels 107a and 107c having the same sensitivity as described above, and the SN ratio can be improved. In this manner, the pixels 107a and 107c constituting the pixel group 110a and the pixel 107b constituting the pixel group 110b can be different from each other in the voltage of a signal output from the pixel when light with a given intensity enters the microlens 131.

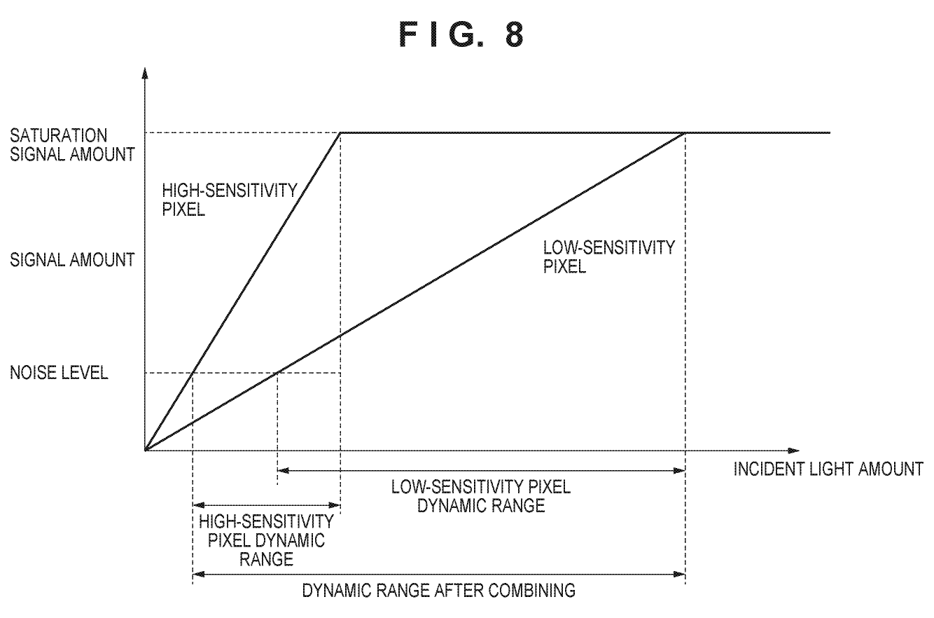

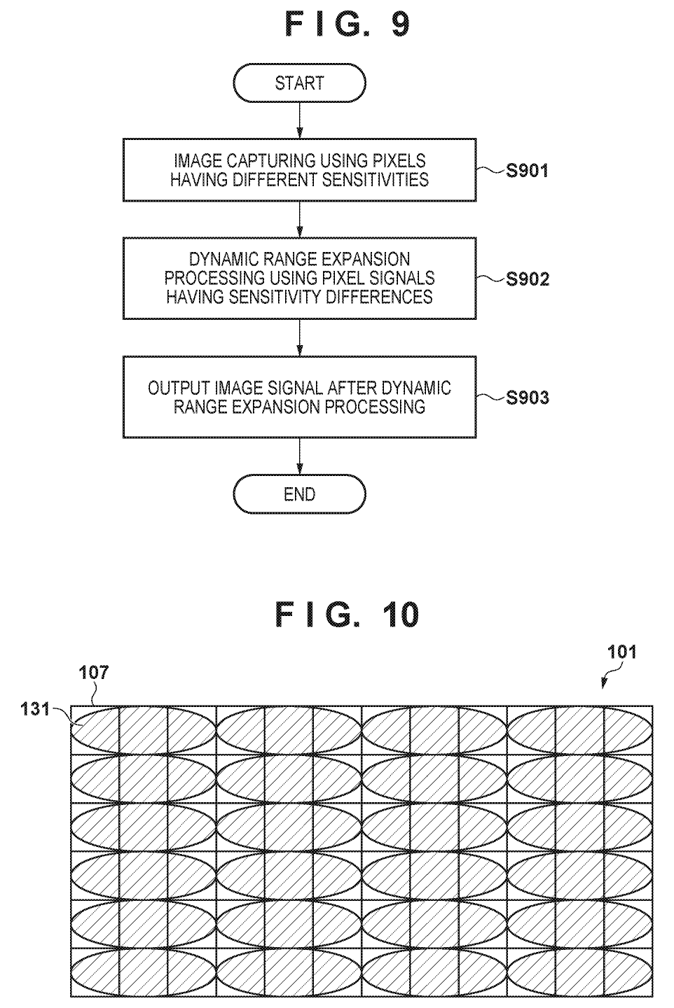

Next, with reference to FIGS. 8 and 9, HDR image capturing using the photoelectric conversion device 100 according to this embodiment will be described. When performing HDR image capturing by combining images captured by multiple pixels 107 having different sensitivities, the high-sensitivity pixels 107 can be used in low-illuminance image capturing, and the low-sensitivity pixels 107 can be used in high-illuminance image capturing, as shown in FIG. 8. By combining these images, image capturing is achieved for objects in a wide illuminance range from low illuminance to high illuminance. Here, HDR image capturing using the low-sensitivity pixels 107 and high-sensitivity pixels 107 has been described. However, the present disclosure is not limited to this, and HDR image capturing may be executed by using the method of changing the capacitance of the FD 113, the method of changing the accumulation time, and the like in combination.

FIG. 9 shows the process procedure of HDR image capturing. First, in step S801, image capturing using the pixels 107 having sensitivities different from each other is performed. Then, pixel signals are read out from the pixels 107, and dynamic range expansion processing is performed using the pixel signals in step S802. By applying the signals with the proper sensitivity to the object, an HDR image with the suppressed highlight blowout and black crushing is obtained. After the expansion processing is performed, an image signal is output in step S903. When reading out the signals from the pixels 107, binning may be executed for each pixel group 110 as described above. In the photoelectric conversion device 100 according to this embodiment, the pixels 107 constituting each pixel group 110 and having the same sensitivity share the FD 113, and binning processing can be executed. Hence, the photoelectric conversion device 100 can implement HDR image capturing with the further improved SN ratio.

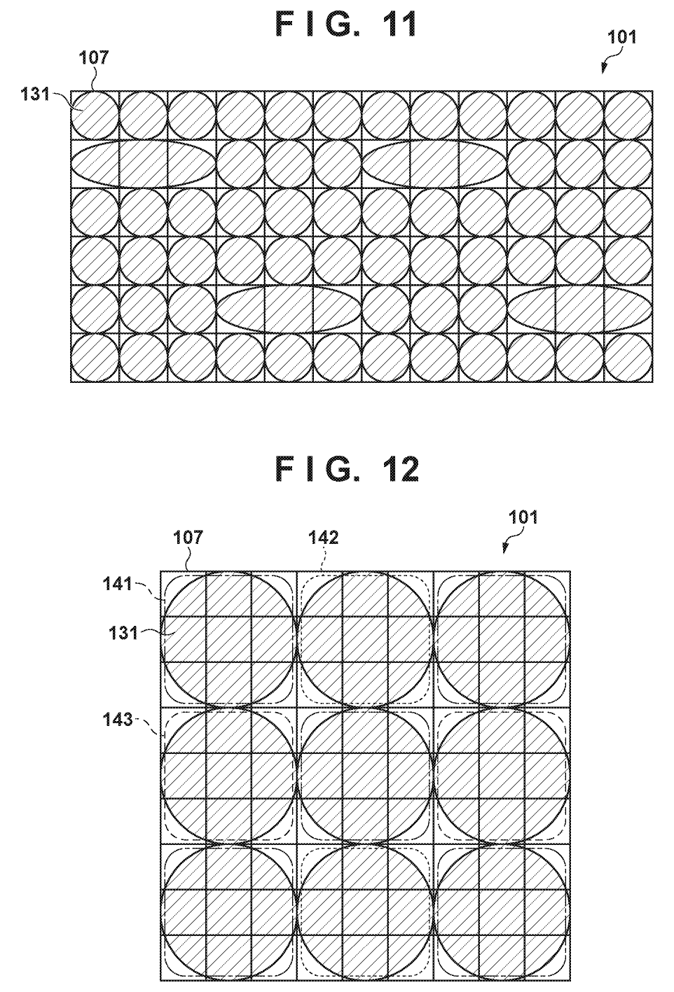

FIGS. 10 and 11 are views each showing an arrangement example of the pixels 107 and the microlenses 131 in the pixel array 101. FIG. 10 shows an example where three pixels 107 arrayed in one direction share one microlens 131. As described above, the pixels 107 having two types of sensitivities are arranged among the pixels 107 due to the microlens 131. By performing image capturing using the pixels 107 having the two types of sensitivities, the HDR image as described above can be obtained. Three pixels 107 arrayed in one direction are shown here, but one microlens 131 may be shared by, for example, four pixels 107 arrayed in one direction. In that case, two pixels 107 in the central portion may have the same sensitivity and constitute the pixel group 110 to share the FD 113, and two pixels 107 at both ends may have the same sensitivity different from the sensitivities of two central pixels 107 and constitute the pixel group 110 to share the FD 113. Five or more pixels 107 arrayed in one direction may share one microlens 131. In that case, the pixels 107 can have a plurality of types of sensitivities.

As shown in FIG. 11, the microlens 131 arranged corresponding to one pixel 107 and the microlens shared by multiple pixels 107 may be mixed in the pixel array 101. In this manner, by arranging the microlenses 131 having different shapes in the pixel array 101, the pixels 107 having different sensitivities can be arranged. Even in this case, the pixels 107 having the same sensitivity constitute the pixel group 110 and share the FD 113, thereby achieving the improved SN ratio due to binning.

FIG. 12 is a view showing the arrangement where the pixels 107 arranged in a matrix of three rows and three columns share one microlens 131. By making the pixels 107 in three rows and three columns to share one microlens 131 and using the sensitivity difference accordingly generated between the pixels 107, for example, HDR image capturing can be performed. In the arrangement shown in FIG. 12, the pixel array 101 includes color filters 141 to 143 arranged in a Bayer array and each arranged for the pixels 107 arranged in three rows and three columns. The color filter 141 transmits green light, the color filter 142 transmits red light, and the color filter 143 transmits blue light. As shown in FIG. 12, the pixels 107 sharing the microlens 131 are covered with the color filters of the same color.

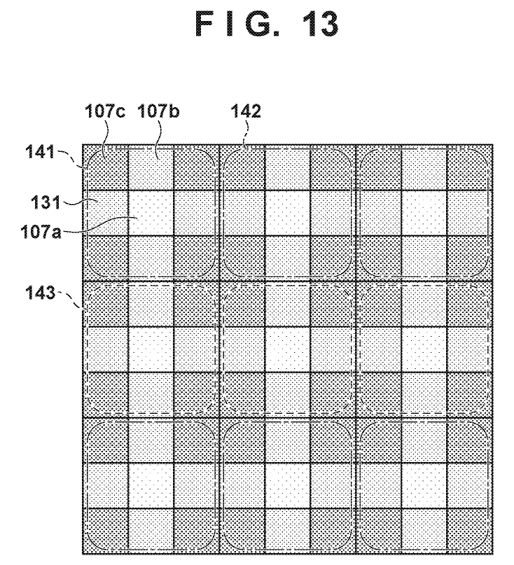

FIG. 13 is a view showing the sensitivity for each pixel 107 generated by the microlens 131 among the pixels 107 arranged in a matrix of three rows and three columns and sharing one microlens 131 shown in FIG. 12. The pixel 107a is located at the center of nine pixels 107 arranged in three rows and three columns and sharing the microlens 131, which is the pixel having the highest sensitivity among the nine pixels 107 arranged in three rows and three columns. The pixels 107c are arranged at four corners in diagonal parts of the pixels 107 arranged in three rows and three columns and sharing the microlens 131, which are the pixels having the lowest sensitivity among the nine pixels arranged in three rows and three columns. The pixels 107b are arranged in opposed side parts of the pixels 107 arranged in three rows and three columns and sharing the microlens 131, and arranged between the pixels 107c at the corners, respectively, which are the pixels having the intermediate sensitivity among the nine pixels arranged in three rows and three columns. In this manner, when the microlens 131 is arranged for the pixels 107 in three rows and three columns, the sensitivity of the pixel 107 changes depending on the position relative to the microlens 131.

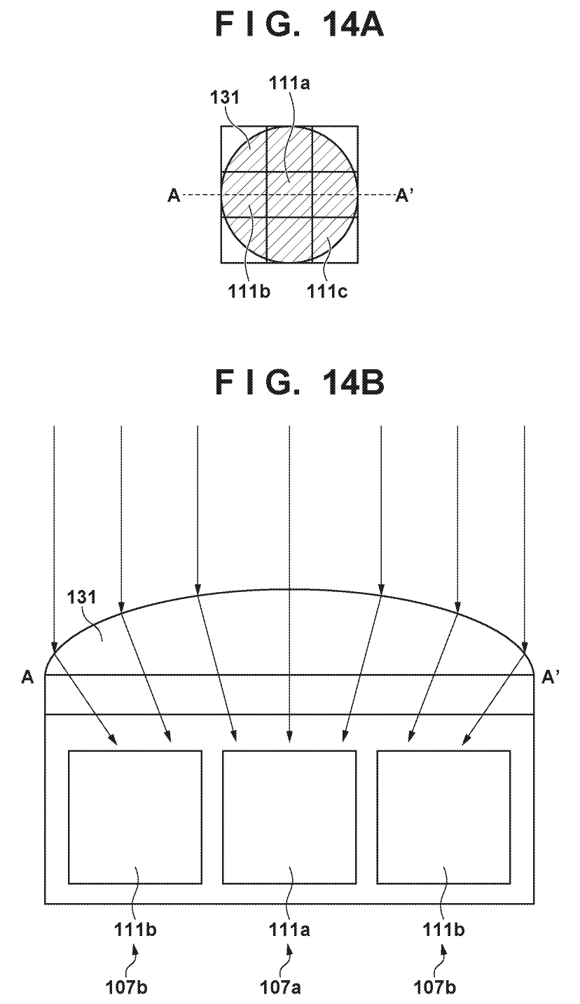

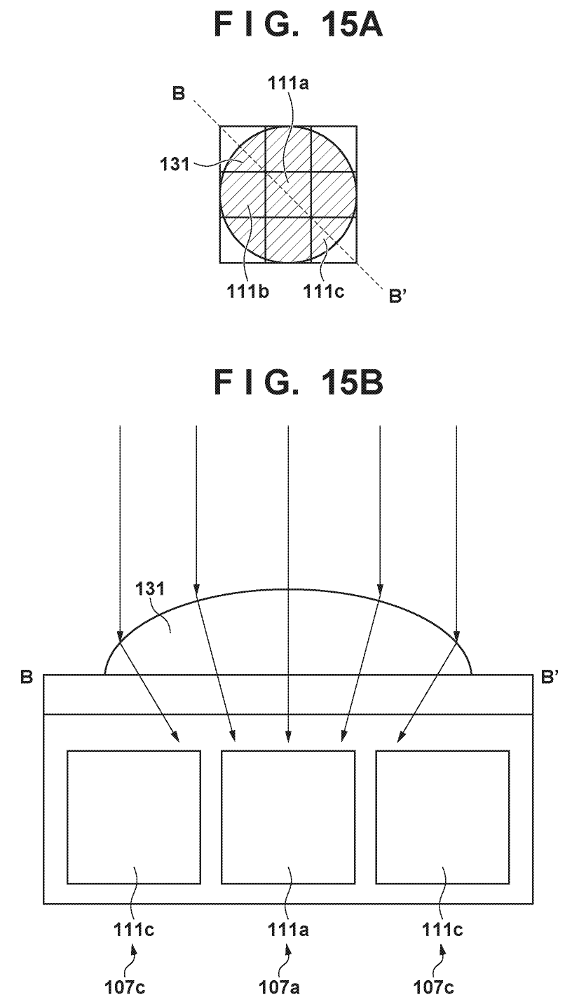

FIG. 14A is a plan view of nine pixels 107 sharing one microlens 131, and FIG. 14B shows a section in an opposite-side direction including the center of the microlens 131 taken along a line A - A' in FIG. 14A. Similarly, FIG. 15A is a plan view of nine pixels 107 sharing one microlens 131, and FIG. 15B shows a section in a diagonal direction including the center of the microlens 131 taken along a line B - B' in FIG. 15A. Each of FIGS. 14B and 15B represents the difference in the amount of light entering the photoelectric conversion element 111 arranged in the pixel 107 generated by the microlens 131. As shown in FIGS. 14B and 15B, due to light condensation by the microlens 131, the pixel 107a (photoelectric conversion element 111a) located at the center of three rows and three columns has the higher sensitivity than the pixels 107b and 107c (photoelectric conversion elements 111b and 111c) located on the periphery sides. Furthermore, among the pixels 107b and 107c (photoelectric conversion elements 111b and 111c) located on the periphery sides, the pixel 107c arranged at a corner receives a small amount of light condensed by the microlens 131, and has a lower sensitivity than the pixel 107b (photoelectric conversion element 111b). In this manner, among the pixels 107 arranged in three rows and three columns and sharing the microlens 131, the pixels 107 having three types of sensitivities are generated due to the difference in amount of light condensed by the microlens 131. That is, when light with a given intensity enters the microlens 131, the largest amount of charges are generated by the photoelectric conversion element 111a of the pixel 107a, and the smallest amount of charges are generated by the photoelectric conversion element 111c of the pixel 107c. The amount of charges generated by the photoelectric conversion element 111b of the pixel 107b is between the amount of charges generated by the photoelectric conversion element 111a of the pixel 107a and the amount of charges generated by the photoelectric conversion element 111c of the pixels 107c. Hence, when light with a given intensity enters via the microlens 131, the pixels 107 can output signals of different voltages for the respective pixel groups 110. Here, in a planar view, the photoelectric conversion elements 111 respectively arranged in the pixels 107 sharing the microlens 131 can have the same size. In a planar view, the photoelectric conversion elements 111 respectively arranged in the pixels 107 sharing the microlens 131 may have the same shape.

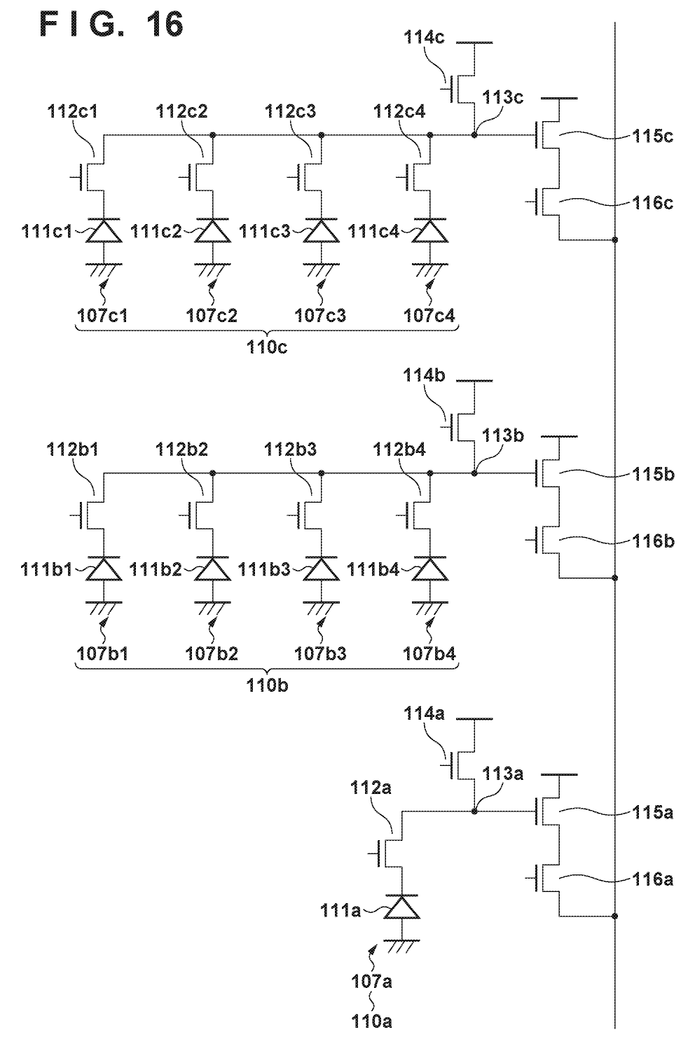

FIG. 16 is a view showing an example of the equivalent circuit including the pixels 107 and the like in the pixel arrangement for sharing one microlens 131 by the pixels 107 arranged in a matrix of three rows and three columns. As shown in FIG. 16, the pixel 107a having the highest sensitivity solely constitutes the pixel group 110a, and the photoelectric conversion element 111a arranged in the pixel 107a is connected to the FD 113a. Four pixels 107b1 to 107b4 having the intermediate sensitivity constitute the pixel group 110b, and photoelectric conversion elements 111b1 to 111b4 arranged in the pixels 107b1 to 107b4 share the FD 113b. Four pixels 107c1 to 107c4 having the lowest sensitivity constitute the pixel group 110c, and photoelectric conversion elements 111c1 to 111c4 arranged in the pixels 107c1 to 107c4 share the FD 113c. When the photoelectric conversion device 100 has this arrangement, binning between the pixels 107 having the same sensitivity as described above can be performed.

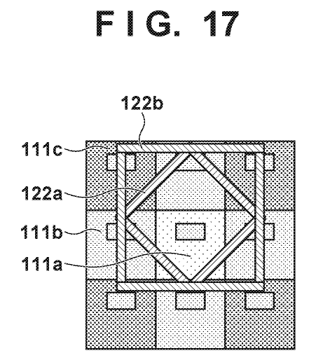

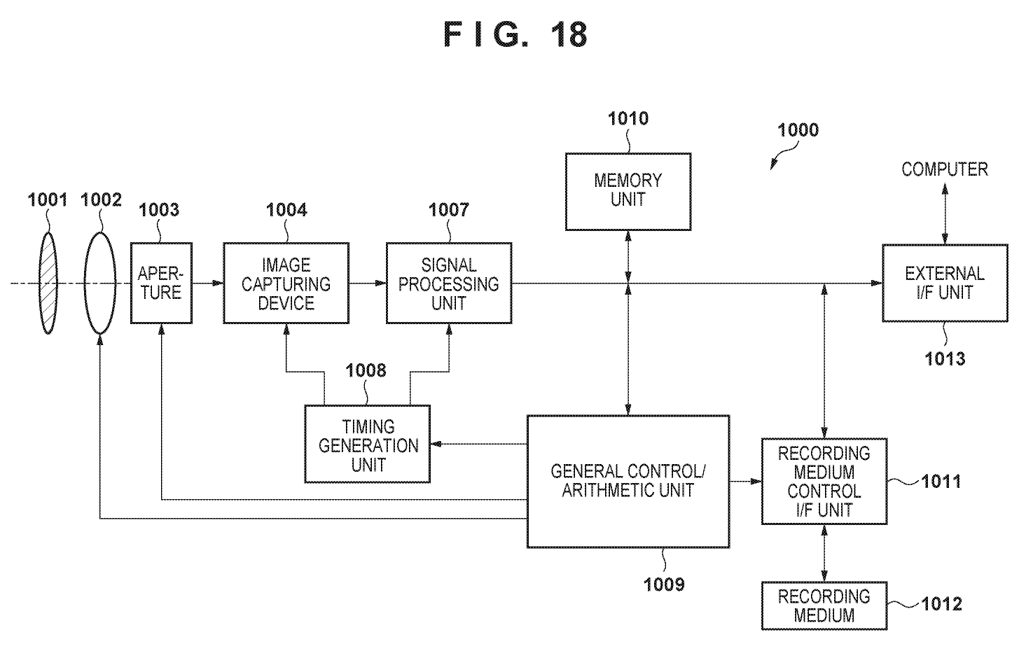

FIG. 17 shows a layout example for sharing the FD 113 in the circuit arrangement shown in FIG. 16. This is the arrangement example for sharing the FD 113 by the pixels 107 having the same sensitivity among the photoelectric conversion elements 111a, 111b, and 111c arranged in the pixels 107a, 107b, and 107c having three types of sensitivities different from each other. The above-described pixel groups 110a, 110b, and 110c are arranged adjacent to each other, but the pixels 107b and 107c (photoelectric conversion elements 111b and 111c) arranged in the same pixel groups 110b and 110c, respectively, are arranged alternately as shown in FIG. 17. Therefore, as in the case shown in FIG. 5B, the wiring sharing FD 122a serving as the FD 113b and the wiring sharing FD 122b serving as the FD 113c shown in FIG. 16 are arranged. In this manner, sharing the FD 113 may be implemented using a plurality of wiring layers.

Application examples of the photoelectric conversion device 100 where the pixel groups 110 each constituted by the pixels 107 (photoelectric conversion elements 111) sharing the FD 113 described above are arranged will be described below.

FIG. 18 is a block diagram showing the schematic arrangement of a photoelectric conversion system. The above-described photoelectric conversion device 100 is applicable to various kinds of photoelectric conversion systems. Examples of photoelectric conversion systems to which the photoelectric conversion device is applicable are a digital still camera, a digital camcorder, a monitoring camera, a copying machine, a facsimile apparatus, a mobile phone, an in-vehicle camera, and an observation satellite. A camera module including an optical system such as a lens and an image capturing device is also included in the photoelectric conversion systems. FIG. 18 exemplarily shows the block diagram of a digital still camera as an example of these.

A photoelectric conversion system 1000 exemplarily shown in FIG. 18 includes an image capturing device 1004 as an example of the photoelectric conversion device, a lens 1002 that forms an optical image of an object on the image capturing device 1004, an aperture 1003 configured to change the amount of light passing through the lens 1002, and a barrier 1001 configured to protect the lens 1002. The lens 1002 and the aperture 1003 form an optical system (optical device) that condenses light to the image capturing device 1004. The image capturing device 1004 is the photoelectric conversion device 100 described above, and converts the optical image formed by the lens 1002 into an electrical signal.

The photoelectric conversion system 1000 also includes a signal processing unit 1007 that is an image generation unit configured to generate an image by processing an output signal output from the image capturing device 1004. The signal processing unit 1007 functions as a processing device that performs an operation of performing various kinds of correction and compression as needed, thereby outputting image data. The signal processing unit 1007 may be formed on a semiconductor substrate on which the image capturing device 1004 is provided or may be formed on a semiconductor substrate different from the image capturing device 1004. In addition, the image capturing device 1004 and the signal processing unit 1007 may be formed on the same semiconductor substrate.

The photoelectric conversion system 1000 further includes a memory unit 1010 configured to temporarily store image data, and an external interface unit (external I/F unit) 1013 configured to communicate with an external computer or the like. Furthermore, the photoelectric conversion system 1000 includes a recording medium 1012 such as a semiconductor memory configured to record or read out image capturing data, and a recording medium control I/F unit 1011 configured to perform record or readout for the recording medium 1012. The recording medium control I/F unit 1011 and the recording medium 1012 can form a part of a recording device. Note that the recording medium 1012 may be incorporated in the photoelectric conversion system 1000 or may be detachable.

Furthermore, the photoelectric conversion system 1000 includes a general control/arithmetic unit 1009 that controls various kinds of operations and the entire digital still camera, and a timing generation unit 1008 that outputs various kinds of timing signals to the image capturing device 1004 and the signal processing unit 1007. The general control/arithmetic unit 1009 and the timing generation unit 1008 can form a part of a control device configured to control an operation of the photoelectric conversion system 1000. In this example, the timing signal and the like may be input from the outside, and the photoelectric conversion system 1000 need only include at least the image capturing device 1004, and the signal processing unit 1007 that processes an output signal output from the image capturing device 1004.

The image capturing device 1004 outputs an image capturing signal to the signal processing unit 1007. The signal processing unit 1007 executes predetermined signal processing for the image capturing signal output from the image capturing device 1004, and outputs image data. The signal processing unit 1007 generates an image using the image capturing signal. Although not shown in FIG. 18, a display device such as a display for displaying the generated image may be arranged in the photoelectric conversion system 1000. As described above, according to this embodiment, it is possible to implement the photoelectric conversion system 1000 to which the photoelectric conversion device 100 (image capturing device) described above is applied.

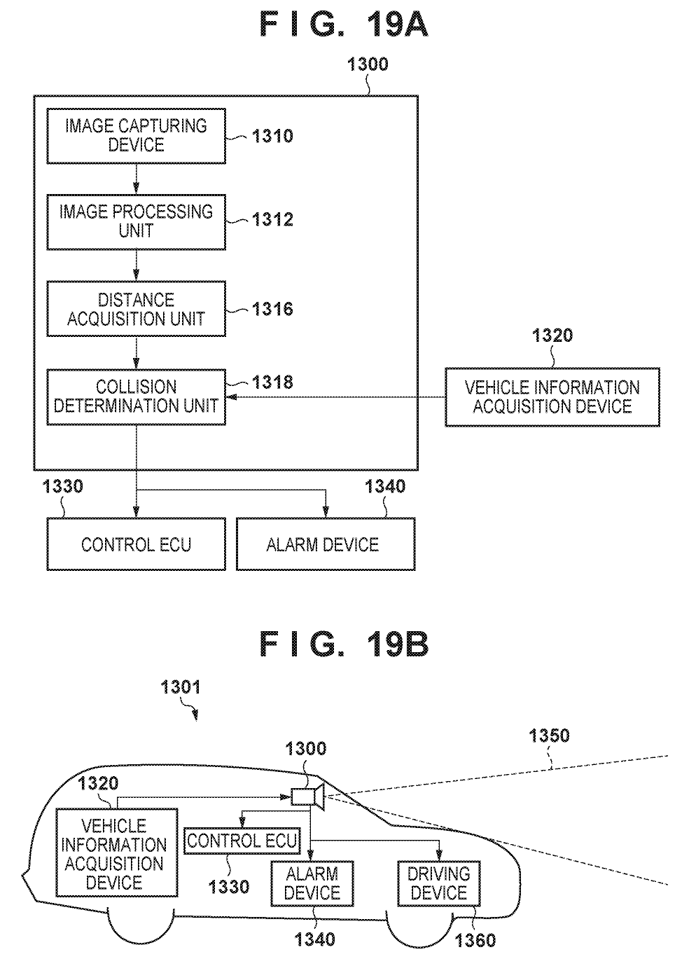

FIGS. 19A and 19B are views showing the configuration of a photoelectric conversion system 1300 and a moving body 1301. FIG. 19A shows an example of a photoelectric conversion system concerning an in-vehicle camera. The photoelectric conversion system 1300 includes an image capturing device 1310. The image capturing device 1310 is the photoelectric conversion device 100 described above. The photoelectric conversion system 1300 includes an image processing unit 1312 that performs image processing for a plurality of image data acquired by the image capturing device 1310. The photoelectric conversion system 1300 also includes a distance acquisition unit 1316 that calculates the distance up to a target object, and a collision determination unit 1318 that determines, based on the calculated distance, whether there is collision possibility. Here, the distance acquisition unit 1316 may acquire distance information up to a target object by using Time of Flight (ToF) method, or may acquire distance information by using parallax information or the like. That is, the distance information is information concerning a parallax, a defocus amount, a distance up to a target object, and the like. The collision determination unit 1318 may determine collision possibility using one of the pieces of distance information. The distance acquisition unit 1316 may be implemented by exclusively designed hardware, or may be implemented by a software module. The distance acquisition unit 1316 may be implemented by a Field Programmable Gate Array (FPGA), Application Specific Integrated Circuit (ASIC), or the like, or may be implemented by a combination of these.

The photoelectric conversion system 1300 is connected to a vehicle information acquisition device 1320, and can acquire vehicle information such as a vehicle speed, a yaw rate, and a steering angle. The photoelectric conversion system 1300 is also connected to an ECU 1330 that is a control device (controller) configured to output a control signal for generating a braking force to the vehicle based on the determination result of the collision determination unit 1318. Furthermore, the photoelectric conversion system 1300 is connected to an alarm device 1340 that generates an alarm to the driver based on the determination result of the collision determination unit 1318. For example, if collision possibility is high as the determination result of the collision determination unit 1318, the ECU 1330 controls a driving device (machine device) 1360 to perform braking, releasing the accelerator pedal, or suppressing the engine output, thereby controlling the vehicle for avoiding collision and reducing damage. The alarm device 1340 sounds an alarm, displays alarm information on the screen of a car navigation system or the like, or applies a vibration to the seat belt or a steering wheel, thereby making an alarm to the user.

In this embodiment, the periphery of the vehicle (moving body 1301), for example, the front or rear side is captured by the photoelectric conversion system 1300. FIG. 19B shows the photoelectric conversion system when capturing the front side (image capturing range 1350) of the vehicle. The vehicle information acquisition device 1320 sends an instruction to the photoelectric conversion system 1300 or the image capturing device 1310. With this configuration, it is possible to further improve the accuracy of distance measurement.

An example in which control is executed so as not to collide with another vehicle has been explained above. The photoelectric conversion system 1300 can also be applied to control of performing automated driving following another vehicle or control of performing automated driving without deviating from a lane. Furthermore, the photoelectric conversion system 1300 can be applied not only to a vehicle such as an automobile but also to, for example, a moving body (moving device) such as a ship, an airplane, or an industrial robot. The moving body includes one or both of a driving force generation unit that generates a driving force mainly used for moving the moving body and a rotating body mainly used for moving the moving body. The driving force generation unit can be an engine, a motor, or the like. The rotating body can be a tire, a wheel, a ship screw, a fan or propeller of an airplane, or the like. In addition, the photoelectric conversion system can be applied not only to a moving body but also to equipment that broadly uses object recognition, such as an intelligent transport system (ITS).

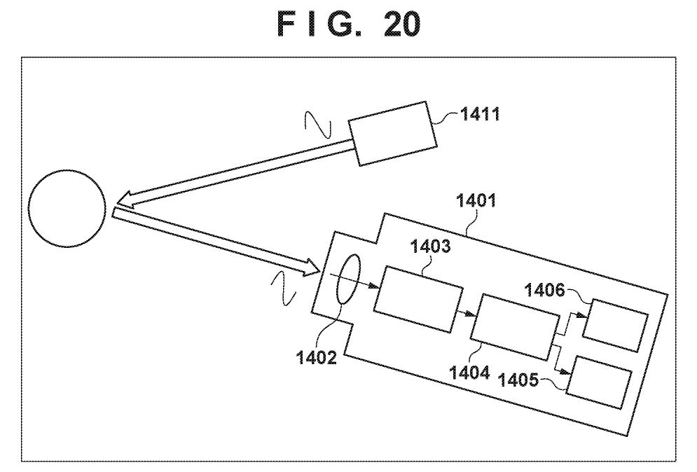

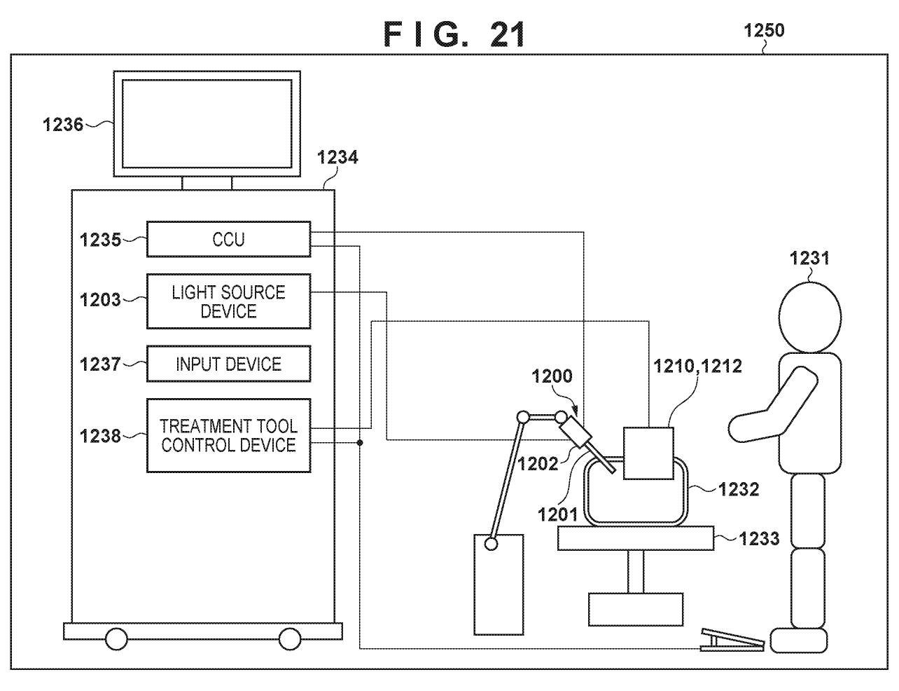

FIG. 20 is a block diagram showing an example of the arrangement of a distance image sensor 1401 as the photoelectric conversion system. As shown in FIG. 20, the distance image sensor 1401 includes an optical system 1402, a photoelectric conversion device 1403, an image processing circuit 1404, a monitor 1405, and a memory 1406. Then, the distance image sensor 1401 can receive light (modulated light or pulsed light) projected from a light source device 1411 toward an object and reflected by the surface of the object, thereby acquiring a distance image corresponding to the distance up to the object.

The optical system 1402 is formed by including one or a plurality of lenses, and guides image light (incident light) from the object to the photoelectric conversion device 1403 and forms an image on the light-receiving surface (sensor portion) of the photoelectric conversion device 1403.

As the photoelectric conversion device 1403, the photoelectric conversion device 100 described above is applied, and a distance signal indicating a distance obtained from a light reception signal output from the photoelectric conversion device 1403 is supplied to the image processing circuit 1404.

The image processing circuit 1404 performs image processing of creating a distance image based on the distance signal supplied from the photoelectric conversion device 1403. Then, the distance image (image data) obtained by the image processing is supplied to and displayed on the monitor 1405, and supplied to and stored (recorded) in the memory 1406.

The distance image sensor 1401 having such arrangement can acquire, for example, a more correct distance image along with improvement in characteristic of pixels by applying the above-described photoelectric conversion device 100.

FIG. 21 is a view showing an example of the schematic arrangement of an endoscopic surgery system 1250 as the photoelectric conversion system according to fourth application example. FIG. 21 shows a state in which an operator (doctor) 1231 operates on a patient 1232 on a patient bed 1233 using the endoscopic surgery system 1250. As shown in FIG. 21, the endoscopic surgery system 1250 is formed from an endoscope 1200, a surgical tool 1210, and a cart 1234 on which various devices for endoscopic surgery are mounted.

The endoscope 1200 includes a lens barrel 1201 including a region of a predetermined length from the distal end, which is inserted into the body cavity of the patient 1232, and a camera head 1202 connected to the proximal end of the lens barrel 1201. In the example shown in FIG. 21, the endoscope 1200 formed as a so-called hard mirror including the hard lens barrel 1201 is shown but the endoscope 1200 may be formed as a so-called soft mirror including a soft lens barrel.

An opening in which an objective lens is fitted is provided at the distal end of the lens barrel 1201. A light source device 1203 is connected to the endoscope 1200, and light generated by the light source device 1203 is guided to the distal end of the lens barrel 1201 by a light guide extended inside the lens barrel 1201, and is emitted to an observation target in the body cavity of the patient 1232 via the objective lens. Note that the endoscope 1200 may be a forward-viewing endoscope or may be a forward-oblique viewing endoscope or side-viewing endoscope.

An optical system and a photoelectric conversion device are provided in the camera head 1202, and reflected light (observation light) from the observation target is condensed by the optical system to the photoelectric conversion device. The observation light is photoelectrically converted by the photoelectric conversion device to generate an electrical signal corresponding to the observation light, that is, an image signal corresponding to an observation image. As the photoelectric conversion device, the photoelectric conversion device 100 (image capturing device) described above can be used. The image signal is transmitted as RAW data to a Camera Control Unit (CCU) 1235.

The CCU 1235 is formed by a Central Processing Unit (CPU), a Graphics Processing Unit (GPU), and the like, and comprehensively controls the operations of the endoscope 1200 and a display device 1236. Furthermore, the CCU 1235 receives an image signal from the camera head 1202, and performs, for the image signal, various kinds of image processes such as development processing (demosaic processing) for displaying an image based on the image signal.

Under the control of the CCU 1235, the display device 1236 displays the image based on the image signal having undergone the image processing by the CCU 1235.

The light source device 1203 is formed from a light source such as a Light Emitting Diode (LED), and supplies, to the endoscope 1200, irradiation light at the time of imaging an operation site or the like.

An input device 1237 is an input interface to the endoscopic surgery system 1250. The user can input various kinds of information or instructions to the endoscopic surgery system 1250 via the input device 1237.

A treatment tool control device 1238 controls driving of an energy treatment tool 1212 for ablation or incision of the tissue, sealing of a blood vessel, or the like.

The light source device 1203 that supplies, to the endoscope 1200, irradiation light at the time of imaging an operation site can be formed from, for example, a white light source formed by an LED, a laser light source, or a combination thereof. If the white light source is formed by a combination of RGB laser light sources, it is possible to accurately control the output intensity and output timing of each color (each wavelength), and thus the light source device 1203 can adjust the white balance of a captured image. In this case, the observation target is time-divisionally irradiated with laser beams from the RGB laser light sources, respectively, and driving of the image sensor of the camera head 1202 is controlled in synchronism with the irradiation timings, thereby making it possible to time-divisionally capture images respectively corresponding to R, G, and B. In this method, it is possible to obtain a color image without providing color filters in the image sensor.

Driving of the light source device 1203 may be controlled to change the intensity of light to be output for every predetermined time. It is possible to time-divisionally acquire images by controlling driving of the image sensor of the camera head 1202 in synchronism with the timing of changing the intensity of the light, and combine the images, thereby generating an image of a high dynamic range without so-called shadow detail loss or highlight detail loss.

The light source device 1203 may be configured to supply light in a predetermined wavelength band corresponding to special light observation. In special light observation, for example, the wavelength dependency of light absorption in the body tissue is used. More specifically, by performing irradiation with light in a narrow band, as compared with irradiation light (that is, white light) at the time of normal observation, predetermined tissue such as a blood vessel in the mucous membrane surface layer is captured with high contrast. Alternatively, in special light observation, fluorescence observation for obtaining an image by using fluorescence generated by performing radiation with excitation light may be performed. In fluorescence observation, it is possible to, for example, irradiate body tissue with excitation light and observe fluorescence from the body tissue, or locally inject a reagent such as indocyanine green (ICG) to body tissue while irradiating the body tissue with excitation light corresponding to the fluorescence wavelength of the reagent, thereby obtaining a fluorescence image. The light source device 1203 can be configured to supply narrow band light and/or excitation light corresponding to such special light observation.

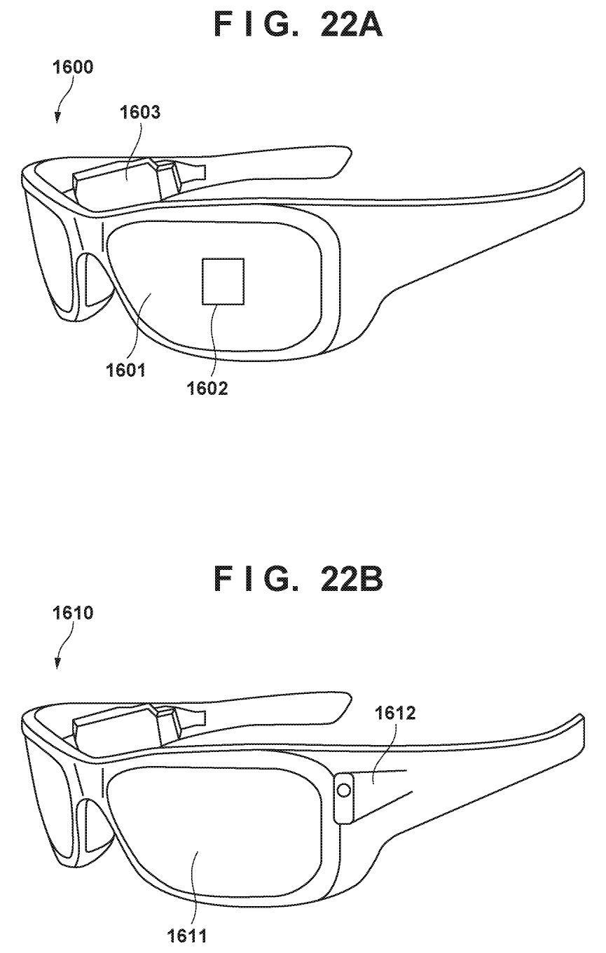

Each of FIGS. 22A and 22B describes glasses 1600 (smartglasses) as the photoelectric conversion system according to the fifth application example. The glasses 1600 shown in FIG. 22A include a photoelectric conversion device 1602. The photoelectric conversion device 1602 is the photoelectric conversion device 100 (image capturing device) described above. A display device including the light emitting device such as an OLED or LED may be provided on the back surface side of a lens 1601. One or a plurality of photoelectric conversion devices 1602 may be provided. Alternatively, a plurality of kinds of photoelectric conversion devices may be used in combination. The arrangement position of the photoelectric conversion device 1602 is not limited to that shown in FIG. 22A.

The glasses 1600 further include a control device 1603. The control device 1603 functions as a power supply that supplies electric power to the photoelectric conversion device 1602 and the above-described display device. In addition, the control device 1603 controls the operations of the photoelectric conversion device 1602 and the display device. An optical system configured to condense light to the photoelectric conversion device 1602 is formed on the lens 1601.

FIG. 22B describes glasses 1610 (smartglasses) according to an application example. The glasses 1610 include a control device 1612, and a photoelectric conversion device corresponding to the photoelectric conversion device 1602 and a display device are mounted on the control device 1612. The photoelectric conversion device in the control device 1612 and an optical system configured to project light emitted from the display device are formed in a lens 1611, and an image is projected to the lens 1611. The control device 1612 functions as a power supply that supplies electric power to the photoelectric conversion device and the display device, and controls the operations of the photoelectric conversion device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a plan view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to this embodiment can include a photoelectric conversion device including a light receiving element, and control a displayed image of the display device based on the line-of-sight information of the user from the photoelectric conversion device.

More specifically, the display device decides a first visual field region at which the user is gazing and a second visual field region other than the first visual field region based on the line-of-sight information. The first visual field region and the second visual field region may be decided by the control device of the display device, or those decided by an external control device may be received. In the display region of the display device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority may be decided from the first display region and the second display region based on line-of-sight information. The first visual field region and the second visual field region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target object ahead the line of sight from the image of the eyeball using the image of the eyeball and the direction of actual viewing of the eyeball in the image as supervised data. The AI program may be held by the display device, the photoelectric conversion device, or an external device. If the external device holds the AI program, it is transmitted to the display device via communication.

When performing display control based on line-of-sight detection, smartglasses further including a photoelectric conversion device configured to capture the image of the outside can be applied. The smartglasses can display the captured outside image information in real time.

According to the present disclosure, a technique advantageous in improving the characteristics of a photoelectric conversion device can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-082853, filed May 16, 2025, which is hereby incorporated by reference herein in its entirety.

What is claimed is:

1. A photoelectric conversion device that comprises a plurality of pixel groups including a first pixel group and a second pixel group arranged to share a microlens, each pixel group being constituted by one or multiple pixels, and color filters covering the plurality of pixel groups and corresponding to a plurality of colors, wherein
photoelectric conversion elements arranged in pixels constituting each pixel group share one floating diffusion,
the first pixel group is constituted by multiple pixels,
the one floating diffusion receives signals which are output from the photoelectric conversion elements arranged in pixels constituting a corresponding pixel group and correspond to color filters of the same color,
a pixel constituting the first pixel group and a pixel constituting the second pixel group are different from each other in the number of charges generated in a case where light with a first intensity enters the microlens.

2. The device according to claim 1, wherein a sensitivity of the pixel arranged in the first pixel group to light with the first intensity and a sensitivity of the pixel arranged in the second pixel group to light with the first intensity are different from each other.

3. The device according to claim 1, wherein the pixel constituting the first pixel group and the pixel constituting the second pixel group are different from each other in a voltage of a signal output from a pixel in a case where light with the first intensity enters the microlens.

4. The device according to claim 1, wherein an accumulation time in the pixel arranged in the first pixel group and an accumulation time in the pixel arranged in the second pixel group during image capturing in the device are different from each other.

5. The device according to claim 1, wherein a magnitude of a capacitance of the floating diffusion arranged in the first pixel group and a magnitude of a capacitance of the floating diffusion arranged in the second pixel group are different from each other.

6. The device according to claim 1, wherein
the first pixel group includes a first pixel and a second pixel,
the second pixel group includes a third pixel,
each of the first pixel and the second pixel generates a first amount of charges in a case where light with the first intensity enters the microlens, and
the third pixel generates a second amount of charges different from the first amount in a case where light with the first intensity enters the microlens.

7. The device according to claim 6, wherein
the second pixel group further includes a fourth pixel, and
the fourth pixel generates the second amount of charges in a case where light with the first intensity enters the microlens.

8. The device according to claim 6, wherein the first pixel, the second pixel, and the third pixel are different in a charge generation amount with respect to light with the first intensity in accordance with an arrangement position relative to the microlens in a planar view.

9. The device according to claim 8, wherein the first pixel and the second pixel are arranged at point-symmetric positions relative to a center of the microlens in a planar view.

10. The device according to claim 9, wherein the third pixel is arranged to overlap the center in a planar view.

11. The device according to claim 8, wherein
the first pixel, the second pixel, and the third pixel are arranged to be arrayed in one direction, and
the third pixel is arranged between the first pixel and the second pixel.

12. The device according to claim 10, wherein
the plurality of pixel groups further include a third pixel group arranged adjacent to the first pixel group and the second pixel group,
the first pixel group, the second pixel group, and the third pixel group share the microlens,
the first pixel group further includes a fifth pixel and a sixth pixel,
the third pixel group includes a seventh pixel, an eighth pixel, a ninth pixel, and a tenth pixel,
each of the fifth pixel and the sixth pixel generates the first amount of charges in a case where light with the first intensity enters the microlens,
each of the seventh pixel, the eighth pixel, the ninth pixel, and the tenth pixel generates a third amount of charges different from the first amount and the second amount in a case where light with the first intensity enters the microlens, and
the first pixel, the second pixel, the third pixel, the fifth pixel, the sixth pixel, the seventh pixel, the eighth pixel, the ninth pixel, and the tenth pixel are arranged in a matrix of three rows and three columns.

13. The device according to claim 12, wherein
the seventh pixel, the eighth pixel, the ninth pixel, and the tenth pixel are arranged at corners of the matrix of three rows and three columns, and
each of the first pixel, the second pixel, the fifth pixel, and the sixth pixel is arranged between pixels included in the third pixel group.

14. The device according to claim 13, wherein
the first amount is larger than the third amount, and
the second amount is larger than the first amount.

15. The device according to claim 1, wherein photoelectric conversion elements respectively arranged in pixels sharing the microlens have the same size and the same shape in a planar view.

16. The device according to claim 1, wherein
the plurality of pixel groups further include a fourth pixel group, and
a pixel constituting the fourth pixel group is shielded from light.

17. The device according to claim 1, wherein pixels sharing the microlens are covered with color filters of the same color.

18. A photoelectric conversion system comprising:
the photoelectric conversion device according to claim 1; and
a signal processing unit configured to generate an image using a signal output from the photoelectric conversion device.

19. A moving body that includes the photoelectric conversion device according to claim 1, comprising
a controller configured to control movement of the moving body by using a signal output from the photoelectric conversion device.

20. Equipment that comprises the photoelectric conversion device according to claim 1, further comprising at least any of:
an optical device corresponding to the photoelectric conversion device;
a control device configured to control the photoelectric conversion device;
a processing device configured to process a signal output from the photoelectric conversion device;
a display device configured to display information obtained by the photoelectric conversion device;
a storage device configured to store information obtained by the photoelectric conversion device; and
a mechanical device configured to operate based on information obtained by the photoelectric conversion device.
